(19) United States
(12) Patent Application Publication
(10) Pub. No.: US 2007/0176297 A1
(43) Pub. Date: Aug. 2, 2007

(54) Reworkable stacked chip assembly

(75) Inventor: Wael Zohni, San Jose, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/344,409

(22) Filed: Jan. 31, 2006

(51) Int. Cl. H01L 23/52

(52) U.S. Cl. 257/777

(57) ABSTRACT

A stacked semiconductor chip assembly utilizing different bonding materials is disclosed. The assembly preferably includes a plurality of units being disposed one above the other, with each unit including at least a semiconductor chip and an interposer. Conductive joining elements are preferably disposed between adjacent units and between one unit and a circuit panel. At least some of the conductive joining elements have lower melting temperatures, than other units so as to allow mounting or rework by melting the lower-melting conductive joining elements while leaving the other conductive joining elements solid.

### BACKGROUND OF THE INVENTION

The present invention relates to semiconductor chip assemblies, and more particularly to semiconductor chip assemblies in which a plurality of chips are stacked one atop the other.

Semiconductor chips are commonly provided as individual, prepackaged units. In such designs, the semiconductor chip is typically mounted to a substrate or chip carrier, which is in turn mounted on a circuit panel, such as a printed circuit board. The circuit board usually has electrical conductors, normally referred to as traces extending in horizontal directions parallel to the surface of the circuit board and contact pads or other electrically conductive elements connected to the traces. The packaged chips are mounted so that terminals disposed on each unit are electrically connected to the contact pads of the circuit board. In this conventional arrangement, the theoretical minimum area of the circuit board must be at least equal to the aggregate areas of all of the terminal-bearing surfaces of the individual prepackaged units. However, in practice, the circuit board must be somewhat larger than this. Thus, space issues often arise. Additionally, traces in these configurations must have significant length and impedance, so that appreciable time is required for propagation of signals along the traces and the speed of operation of the circuit is limited.

While various approaches have been proposed for alleviating these drawbacks, the “stacking” of units above one another in a common package is often employed. Essentially, in this type of design, the package itself has vertically extending conductors that are connected to the contact pads of the circuit board. In turn, the individual chips within the package are connected to these vertically extending conductors. Because the thickness of a chip is substantially smaller than its horizontal dimensions, the internal conductors can be shorter than the traces on a circuit board that would be required to connect the same number of chips in a conventional arrangement. Examples of such stacked package designs are taught in, U.S. Pat. Nos. 5,861,666, 5,198,888, 4,956,694, 6,072,233 and 6,268,649; and U.S. Patent Publication No. 2003/0107118 A1, the disclosures of which are hereby incorporated by reference herein. Often times, the vertically extending conductors, or buses, are in the form of solder balls or the like, which connect the prepackaged units to each other and to the circuit board.

Typically, during assembly of such a stacked package assembly, the individual units are each initially assembled, including the individual bonding of solder balls or the like thereto. Thereafter, the individual packages may be stacked one atop the other, so that they overlie one another and form a subassembly. In this position, the corresponding connections of the different packages are aligned so as to be in contact and form electrical connections. In addition, the now stacked subassembly of the various packages is aligned with the circuit panel, so as to form one completed connection between all of the units and the circuit board. While the units are held together in this arrangement, heat is applied so as to reflow the solder of the solder balls, thereby fusing the aligned balls and connections of the individual components into continuous electrical conductors. Alternatively, prior to connection to the circuit board, the reflow step may be performed to the individual prepackaged units, to form a prefabricated subassembly. This subassembly can thereafter be connected to a circuit board or the like, in a similar fashion as described above.

Although the use of such solder balls or other conductive joining elements allows for easy assembly of the overall stacked package assembly, they do have their drawbacks. For example, movement of the components of the stacked package assembly may be useful and/or required subsequent to the initial attachment of the individual stacked units to the circuit board. This necessarily requires the unfusing of the different components. However, the standard step of applying heat to cause the reflow of the aforementioned solder balls or the like causes all of them to become detached from their previously established connections. Thus, all of the individual prepackaged units become detached from one another, when it may be advantageous to have them remain in their stacked subassembly and become detached from the circuit board.

Therefore, there exists a need for a stacked package assembly which allows for individual prepackaged units to remain connected to one another when they are detached from a circuit board or the like.

### SUMMARY OF THE INVENTION

A first aspect of the present invention is a semiconductor chip assembly. In accordance with this first aspect, the semiconductor chip assembly preferably includes a plurality of units being disposed one above the other, the units each including a semiconductor chip and an interposer. The chip assembly also preferably includes a plurality of first conductive joining elements connected to certain of the units and a plurality of second conductive joining elements connected to at least one of the plurality of units. The plurality of first conductive joining elements are preferably capable of providing electrical connections between the units, and the plurality of second conductive joining elements are preferably capable of providing an electrical connection between the assembly and an external circuit. Preferably the melting temperature properties of the first conductive joining elements are different from those of the second conductive joining elements.

In certain embodiments of this first aspect, the melting temperature of the plurality of second conductive joining elements is less then the melting temperature of the first conductive joining elements. In other embodiments, the chip assembly may include an external circuit, with the second conductive joining elements connecting at least one of the units to the external circuit. The external circuit may be a circuit board or the like. In different embodiments, the first and second conductive joining elements may include metallic cores and metallic bonding material overlying the cores, metallic rods and metallic bonding material, or a flowable conductive polymeric composition. The plurality of first conductive joining elements may be located between adjacent units and the plurality of second conductive joining elements may be located between one of the units and a circuit panel. Additionally, in certain embodiments, the semiconductor chip assembly may further include a plurality of third conductive joining elements connected to at least one of the plurality of units. The plurality of third conductive joining elements preferably has different melting temperature properties than those of the first and second conductive joining elements.

A second aspect of the present invention is a method of reworking a stacked chip assembly. The assembly preferably includes a semiconductor chip assembly having a plurality of units being disposed one above the other, and a plurality of first conductive joining elements connecting at least some of the units with one another. The assembly preferably also includes an external circuit and a plurality of second conductive joining elements having a melting temperature lower than the melting temperature of the first conductive jointing elements connecting at least one of the plurality of units to the external circuit elements. The method in accordance with this second aspect preferably includes the steps of applying heat to the semiconductor chip assembly so as to melt at least a portion of the second conductive joining elements without melting the first conductive joining elements and moving the assembly with respect to the external circuit.

In other embodiments of this second aspect, the method may further include the step of reattaching the assembly to the external circuit. Additionally, the step of applying heat to the semiconductor chip assembly so as to melt at least a portion of the first conductive joining elements is also contemplated.

A third aspect of the present invention is a stacked chip assembly, which preferably includes a circuit board, a plurality of units being disposed on above the other, the units being connected together by a plurality of first conductive joining elements providing electrical connections between the units, and an end unit connected to at least one of the plurality of units by a plurality of the first conductive joining elements and the circuit board by a plurality of second conductive joining elements providing electrical connections between the end unit and the circuit board. Preferably, in accordance with this third aspect, the second conductive joining elements melt at a lower temperature than the first conductive joining elements.

### BRIEF DESCRIPTION OF THE DRAWINGS

A more complete appreciation of the subject matter of the present invention and the various advantages thereof can be realized by reference to the following detailed description in which reference is made to the accompanying drawings in which:

FIG. 1 is a diagrammatic exploded view of a chip assembly in accordance with one embodiment of the invention.

FIG. 2 is a fragmentary, diagrammatic sectional view of the chip assembly depicted in FIG. 1.

FIG. 3 is a fragmentary sectional view of a chip assembly in accordance with another embodiment of the present invention.

FIG. 4 is a view similar to FIG. 3 but depicting an assembly according to yet another embodiment of the invention.

### DETAILED DESCRIPTION

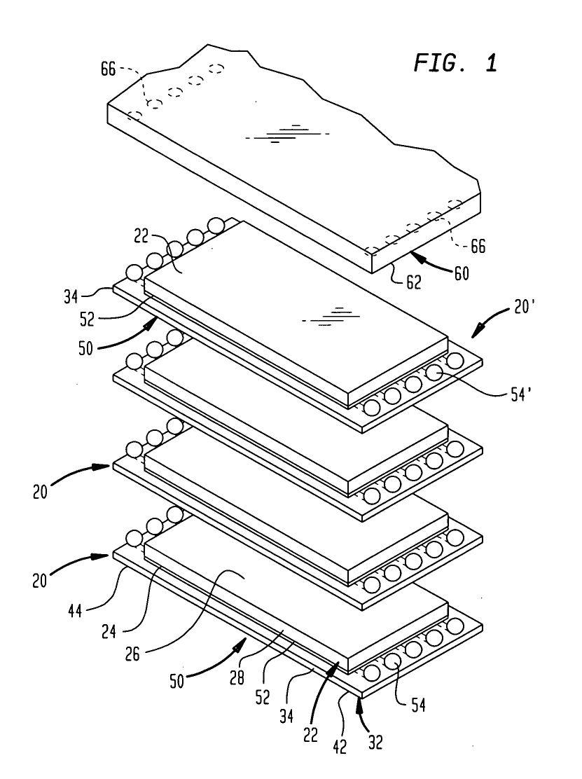

A stacked package according to one embodiment of the invention is illustrated in FIG. 1. This assembly includes a plurality of chip and substrate units 20. Each unit 20 preferably includes a semiconductor chip 22, which is generally in the form of a rectangular solid having a front face 24, an oppositely directed rear face 26, and edges 28 extending between the front and rear faces. Preferably, each chip 22 has a plurality of contacts 30 on front face 24 connected to other internal electronic components (not shown). The contacts are arranged in two rows adjacent to opposite edges 28 of each chip. In the assembly illustrated, the various chips are identical to one another in physical configuration and in internal structure. For example, the various chips may be memory chips. However, the various chips do not need to be identical to one another. Also, the contacts may be provided at any location on the front face of each chip as, for example, in rows adjacent to the center of the front face or in an array on all or a portion of the front face.

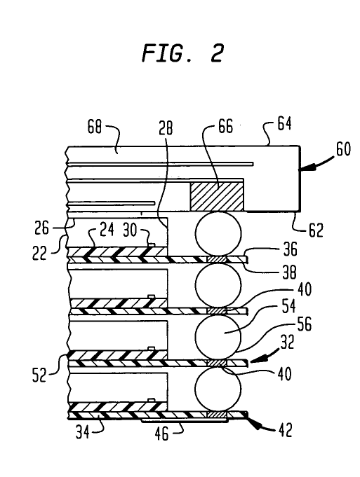

Each unit 20 preferably further includes an interposer 32, which, in turn, includes a generally planar dielectric layer 34 having a first surface 36 and a second, opposite surface 38. Each interposer 32 further includes metallic pads 40 aligned with holes in dielectric layer 34 so that each pad is exposed at surface 36 and surface 38 in a peripheral region 42 of the interposer, adjacent one edge of dielectric layer 34 (best shown in FIG. 2). Each interposer has similar pads (not shown) in a further peripheral portion 44 adjacent the opposite edge of dielectric layer 34. Metallic leads 46 (FIG. 2) preferably extend along each dielectric layer from a central region 50 of the interposer to the peripheral regions 42 and 44. Each lead 46 is electrically connected to one of the pads 40 in a peripheral region of the interposer.

Chip 22 of each unit 20 is preferably mounted on the central region 50 of interposer 32, with front or contact-bearing face 24 of the chip facing towards first side 36 of dielectric layer 34. Contacts 30 of each chip are connected to leads 46 of dielectric layer 34 so that each contact 30 is connected to one lead 46 and one pad 40. Although not shown in FIGS. 1 and 2, the electrical connections between contacts 30 and leads 46 may include flexible portions of leads 46 or wire bonds, as are well known in the art. A layer of a compliant material such as a gel or an elastomer 52 optionally may be disposed between front face 24 of each chip 20 and surface 36 of dielectric layer 34. Thus the dielectric layer of each unit is mechanically decoupled from the chip and free to deform and deflect independently of the chip. In this case, pads 40 can also move relative to contacts 30 on the chip without damage to the electrical interconnection.

Each unit 20 further includes first conductive joining elements 54, such as metallic balls or the like. First joining elements 54 are formed from a first bonding material, such as solder, for bonding the element to pads 40 on first surface 36 of dielectric layer 34. In a preferred embodiment, the first conductive joining elements are provided as plain masses or balls 54 constructed entirely of solder. This first bonding material or solder is preferably capable of being reflowed to bond balls 54 to pads 40. As best seen in FIG. 2, the diameter of each ball 54 is approximately equal to the combined thickness of compliant layer 52 and chip 22, or slightly larger than this combined thickness. The balls are further preferably arranged in rows along the peripheral regions 42 and 44 so that the balls are disposed alongside the chips.

The assembly further preferably includes a circuit panel 60 having a first side 62, a second side 64, and metallic contact pads 66 disposed in rows on the first side 62 of the panel. Panel 60 further has electrical conductors 68, some of which extend to contact pads 66. Conductors 68 are preferably arranged in the conventional manner to provide interconnections with additional circuit elements (not shown).

As best shown in FIG. 1, the stacked assembly includes at least one unit which is positioned closest to the circuit panel 60. This unit will be referred to herein as the end unit 20′. In the embodiment depicted, end unit 20′ is identical to the other units 20 of the overall stacked assembly, with exception of second conductive elements or balls 54′. Each ball 54′ is similar to first conductive elements or balls 54, as described above, but is constructed of a second bonding material such as solder which is capable of being reflowed at a lower temperature than first bonding material. Thus, upon the application of heat, balls 54′ melt before balls 54 do. As will be made apparent below, this may be beneficial during the construction of a stacked package assembly, especially during reworking after circuit panel or board mounting.

In a preferred embodiment, balls 54 are masses of solder, as discussed above, and may be constructed of many different types of solder alloys. For example, in certain embodiments balls 54 may be constructed of 63Sn37Pb, 97Sn2.5Ag0.5Cu, or 97Sn3Ag, among other different solder alloys. Balls 54′ are also masses of solder, but constructed of a lower melt temp solder than that of balls 54. However, it is noted that the above examples only indicated preferred constructions, and other constructions are clearly envisioned, including the use of different materials suitable for use in connection with the present invention. For example, a flowable conductive polymeric composition such as a metal-filled thermoplastic polymer may be utilized as first and/or second bonding materials. A metal-filled thermosetting polymer, which does not melt may be used as the first bonding material. Additionally, eutectic bonding or diffusion-bonding alloys may be used, preferably as the first bonding material. A first bonding material with a higher melting temperature would preferably be associated with the above described first conductive joining elements, and a second bonding material with a lower melting temperature preferably would be associated with the above described second conductive joining elements.

In an assembly process according to one embodiment of the invention, the individual units, as described above, are fabricated. Each unit can be tested separately by engaging pads 40 with contacts of a test socket, or by engaging conductive elements or balls 54, 54′ in a socket. The chip, leads and connections can then be tested by actual operation of the chip. After testing, the individual units are stacked one atop the other as shown in the drawings, so that the chips 22 of all of the units overlie one another in front face to rear face disposition, and so that peripheral portions 42 and 44 of the various interposers are aligned with one another. In this arrangement, pads 40 on the various interposers and balls 54 associated therewith are also aligned with one another. Thus, each ball 54 associated with each pad 40 on one interposer 32 makes contact with the corresponding pad 40 on the next interposer 32 in the stack. This forms a stacked subassembly, which may thereafter be aligned with circuit panel 60 so that contact pads 66 are aligned with the aforementioned stacked balls and pads. While the components are held together in this arrangement, heat is applied so as to reflow the solders of the first and second conductive joining units 54 and 54′, thereby fusing the aligned balls and pads of all of the units into continuous electrical connection with one another and with circuit panel 60. Thus, each such conductor extends vertically through the entire stack and is fused to one contact pad 66 of the circuit panel. In a variant of this assembly process, the units 20 and 20′ may be stacked as described above with the first conductive joining units 54, but without second conductive joining units 54′ on the end unit 20′. The stacked units may be heated so as to temporarily melt or reflow the first conductive joining units and then cooled to bond the units 20 and 20′ to one another. This partial assembly may be tested in this condition, and may be handled, stocked and shipped as a unit. The partial assembly is assembled to the circuit panel with the second conductive joining units carried either on the end unit 20′ or on the circuit panel, and the second conductive joining units 54′ are reflowed to bond the end unit 20′, and hence the other units as well, to the circuit panel and complete the vertical conductors discussed above. This step may be performed by heating to at a temperature sufficient to melt second conductive joining units 54′ but desirably below the melting temperature of the first conductive joining units 54. Thus, the units 20 and 20′ remain fixed to one another during attachment to the circuit panel and during rework.

Despite all of the care taken in the assembly process, it may still be necessary to rework the assembly as by removing the stacked units from the circuit panel 60 or repositioning the stacked units on the circuit panel. Such rework can be performed by heating the assembly so as to melt the second bonding material of units 54′ associated with the connection between end unit 20′ and circuit panel 60, most preferably without melting the first bonding material 54. For example, the entire assembly may be heated to a temperature above the lowest melting temperature (also referred to as the “solidus” temperature) of the second bonding material but below the lowest melting temperature or solidus temperature of the first bonding material. This weakens the connection between unit 20′ and circuit panel 60, while keeping the remaining units 20 connected to each other and unit 20′. After the application of heat, the entire subassembly may be detached and moved with respect to the circuit panel so as to align with different contact pads 66 or other connections of circuit panel 60, or to completely disconnect the stacked units from the circuit panel. Complete disconnection of units 20, 20′ may allow for them to be connected or placed adjacent to a machine suitable for testing of the stacked subassembly. This is highly beneficial for easily fabricating and testing stacked packages.

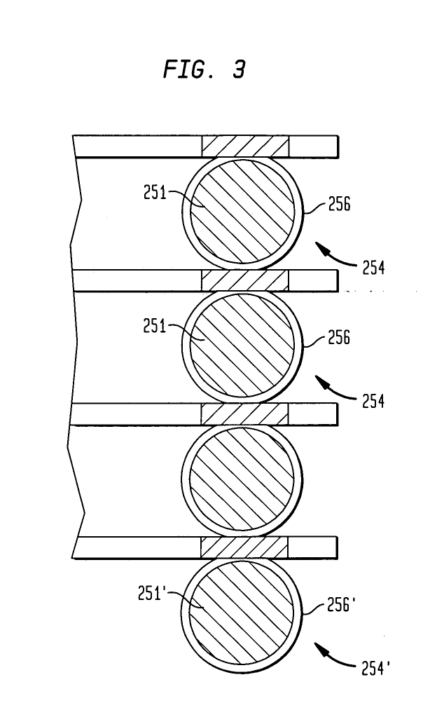

In an alternate embodiment (FIG. 3), the first conductive joining units 254 are solid core solder balls. Each first conductive joining unit includes a core 251 formed from and a coating of a first bonding material, such as a first solder 256. In the embodiment of FIG. 3, the second conductive joining units 254′ include similar cores 251 and coatings of a second bonding material, such as a second solder 256′, having a melting temperature lower than that of the first conductive bonding material. Cores 251 and 251′ may be formed from the same or different conductive or non-conductive materials. The materials of the cores desirably have melting temperatures above the melting temperatures of the bonding materials. For example, the cores may be formed from copper. In the assembly process discussed above, only the coatings 256 and 256′ are melted. In the rework process discussed above, the coatings 256′ of the second conductive units melt when the assembly is heated, whereas the coatings 256 of the first conductive units remain solid, so that the various parts of the assembly remain connected by the first conductive units.

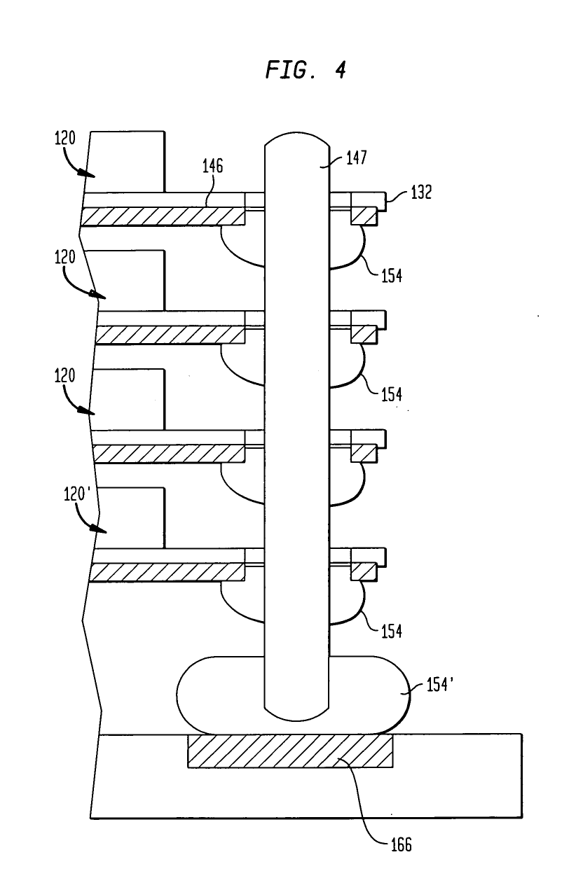

The vertical conductors may be formed by processes other than the specific stacking process discussed above. For example, as shown in FIG. 4, the interposer 132 of each unit 120,120′ may be formed with holes or notches at the outer ends of leads 146. Electrically conductive rods 147 or the like may be inserted through such holes or notches. The rods may be bonded to the outer ends of leads 146 by reflowing solder or another first bonding material to form first masses of bonding material 154 which connect the units 120 to the rods and thus connect the units to one another. Second masses of conductive bonding material 154′ are applied to the rods 147 at or near the ends of the rods so that the second masses are extend beyond end unit 120′. The second masses connect the rods, and hence all of the units 120, 120′, to a conductive feature 166 of an external circuit. The first bonding material used in first masses 154 has a higher melting temperature than the second masses 154′. This assembly also can be bonded to the external circuit, and reworked, while the connections between the units remain intact.

The improvements set forth in the present invention may be beneficial to and adapted to cooperate with many different stacked package configurations. The orientation of the stack relative to the circuit panel or other external circuit element is immaterial; FIG. 1 depicts the end unit 20′, and the lower-melting, second conductive joining units, at the top of the stack, whereas FIGS. 3 and 4 show the these features at the bottom of the stack.

In a further variant, a stack may include two or more smaller stacks, with the lower-melting, second conductive joining units at each boundary between the smaller stacks, and with the higher-melting first conductive joining units at other locations, within at least one of the smaller stacks. Thus, upon the application of a suitable amount of heat, certain of the units may be removed from other of the units, while the smaller stacks having first conductive joining units remain intact. Such a configuration may be useful in testing certain of the various units or unit combinations. In addition, more than one unit may include such a lower melting temperature bonding material, such that more than one detachment may be seen upon application of a suitable heat.

Finally, it is contemplated to provide a stacked assembly that utilizes more than two bonding materials that melt at different temperatures. For example, a stacked assembly may include a first bonding material which melts at a temperature X, a second bonding material which melts at a temperature Y, and a third bonding material which melts at a temperature Z. In such a configuration, depending upon the desires of a person working with the assembly, certain of the units may be detached upon the application of a heat at temperature X. Thereafter, certain of the remaining units may be detached upon the application of a heat at temperature Y. This may be beneficial in situations where it is useful to separately test certain units or combinations of units after an initial assembly. The particular situation of these different melting temperature bonding materials within the stack of units is not limited. Further, it is contemplated that more than three different melting temperature bonding materials may be utilized.

As mentioned above, there exist many different stacked package assembly configurations and designs known in the art. Although only certain specific stacked package designs are referred to above, the present invention can be used in other stacked package designs. In one variant, more than one chip can be provided on each level of the assembly. Thus, each interposer may be arranged to mount two chips side-by-side. When the interposers and chips are stacked atop one another, they form two stacks of chips side by side. The regions of each interposer bearing the conductive joining elements may include a middle region disposed between the two stacks. The leads from both chips may extend to such a middle region, and the vertical conductors of the assembly may extend through the superposed middle regions.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A semiconductor chip assembly comprising:
a plurality of units being disposed one above the other, said units each including a semiconductor chip and an interposer;
a plurality of first conductive joining elements connected to certain of said units, said first conductive joining elements providing electrical connections between said units; and
a plurality of second conductive joining elements connected to at least one of said plurality of units, said plurality of second conductive joining elements being capable of providing an electrical connection between the assembly and an external circuit,
wherein the melting temperature properties of said first conductive joining elements are different from those of said second conductive joining elements.

2. The semiconductor chip assembly according to claim 1, further comprising an external circuit, said second conductive joining elements connecting at least one of said units to said external circuit.

3. The semiconductor chip assembly according to claim 4, wherein said external circuit includes a circuit board.

4. The semiconductor chip assembly according to claim 1, wherein the melting temperature of said second conductive joining elements is less then the melting temperature of said first conductive joining elements.

5. The semiconductor chip assembly according to claim 4, wherein said first conductive joining elements are constructed entirely of a first solder.

6. The semiconductor chip assembly according to claim 5, wherein said second conductive joining elements are constructed entirely of a second solder different from said first solder.

7. The semiconductor chip assembly according to claim 4, wherein at least one of said first conductive joining elements and said second conductive joining elements include metallic cores and metallic bonding material overlying said cores.

8. The semiconductor chip assembly according to claim 4, further comprising electrically conductive rods, said first conductive joining elements connecting said units to said rods, said second conductive joining elements being disposed on said rods and exposed for connection to an external circuit element.

9. The semiconductor chip assembly according to claim 4, wherein at least one of said first conductive joining elements and said second conductive joining elements includes a conductive polymeric composition.

10. The semiconductor chip assembly according to claim 9, wherein said conductive polymeric composition is a metal-filled epoxy.

11. The semiconductor chip assembly according to claim 1, further comprising a plurality of third conductive joining elements connected to at least one of said plurality of units, said plurality of third conductive joining elements being capable of providing an electrical connection, wherein the melting temperature properties of said third conductive joining elements are different from those of said first and second conductive joining elements.

12. A method of reworking a stacked chip assembly including (i) a semiconductor chip assembly having a plurality of units being disposed one above the other, and a plurality of first conductive joining elements connecting at least some of said units with one another; (ii) an external circuit; and (iii) a plurality of second conductive joining elements having a melting temperature lower than the melting temperature of said first conductive joining elements connecting at least one of said plurality of units to the external circuit element, the method comprising:
applying heat to said semiconductor chip assembly so as to melt at least a portion of said second conductive joining elements without melting said first conductive joining elements; and
moving said assembly with respect to said external circuit.

13. The method according to claim 12, further comprising the step of reattaching the assembly to said external circuit.

14. The method according to claim 12, wherein said plurality of second conductive joining elements are located between one of said plurality of units and a circuit panel.

15. The method according to claim 14, wherein said moving step includes removing said semiconductor chip assembly from said circuit panel.

16. The method according to claim 12, further comprising the step of applying heat to said semiconductor chip assembly so as to melt at least a portion of said first conductive joining elements.
